(19) United States
(12) Patent Application Publication
(10) Pub. No.: US 2025/0133908 A1
(43) Pub. Date: Apr. 24, 2025

(54) DISPLAY DEVICE, DISPLAY PANEL AND MANUFACTURING METHOD THEREFOR

(71) Applicant: BOE TECHNOLOGY GROUP CO., LTD., BEIJING (CN)

(72) Inventor: Yingtao WANG, Beijing (CN)

(73) Assignee: BOE TECHNOLOGY GROUP CO., LTD., BEIJING (CN)

(21) Appl. No.: 18/574,725

(22) PCT Filed: Dec. 29, 2021
(86) PCT No.: PCT/CN2021/142709

§ 371 Date: Dec. 27, 2023

(51) Int. Cl. H10K 59/122; H10K 59/12

(52) U.S. Cl. CPC H10K 59/122; H10K 59/1201

(57) ABSTRACT

A display panel comprises a driving backplane, a first electrode layer, and a separation layer, disposed on the side of the driving backplane same as the first electrode layer. The separation layer includes a support layer and a cutoff layer. Each of the first electrodes is exposed by the support layer. An orthographic projection of the cutoff layer on the driving backplane and an orthographic projection of the first electrode on the driving backplane are spaced apart. The separation layer is includes a cut groove including a first groove located on the support layer and a second groove located on the cutoff layer, and an orthographic projection of at least one side wall of the second groove on the driving backplane is located between orthographic projections of boundaries of two side walls of the first groove away from a surface of the driving backplane on the driving backplane.

### CROSS REFERENCE

The present application is a U.S. national phase application of International Application No. PCT/CN2021/142709, filed on Dec. 29, 2021, and the entire contents thereof are incorporated herein by reference.

### TECHNICAL FIELD

The present disclosure relates to the field of display technology, and in particular, to a display device, a display panel, and a manufacturing method of display panel.

### BACKGROUND

With the development of display technology, display panels have been widely used in various electronic devices such as mobile phones to achieve image display and touch operations. OLED (Organic Light-Emitting Diode) display panel is a common one.

It should be noted that, information disclosed in the above background portion is provided only for better understanding of the background of the present disclosure, and thus it may contain information that does not form the prior art known by those ordinary skilled in the art.

### SUMMARY

The present disclosure provides a display device, a display panel, and a manufacturing method of the display panel.

According to an aspect of the present disclosure, a display panel is provided, including:
a driving backplane;
a first electrode layer, disposed on one side of the driving backplane and including a plurality of first electrodes distributed at intervals;
a separation layer, disposed on the side of the driving backplane same as the first electrode layer; wherein the separation layer includes a support layer and a cutoff layer stacked in a direction away from the driving backplane; a material of the support layer is an insulating material and each of the first electrodes is exposed; an orthographic projection of the cutoff layer on the driving backplane and an orthographic projection of the first electrode on the driving backplane are spaced apart; the separation layer is configured with a cut groove located elsewhere of the first electrode, the cut groove includes a first groove located on the support layer and a second groove located on the cutoff layer, an orthographic projection of at least one side wall of the second groove on the driving backplane is located between orthographic projections of boundaries of two side walls of the first groove away from a surface of the driving backplane on the driving backplane;
a light-emitting layer, covering the separation layer and the first electrode; and
a second electrode, covering the light-emitting layer.

In an exemplary embodiment of the present disclosure, the separation layer includes a support layer and a cutoff layer stacked in a direction away from the driving backplane;
each of the first electrodes is exposed by the support layer, and a material of the support layer is an insulating material; the cutoff layer is located inside the boundary of the support layer and is insulated from the first electrodes; and
the first groove is located at the support layer, and the second groove is located at the cutoff layer.

In an exemplary embodiment of the present disclosure, the separation layer includes a plurality of pixel openings exposing each of the first electrodes, and boundaries of each pixel opening are located inside boundaries of the first electrodes exposed by the pixel opening.

In an exemplary embodiment of the present disclosure, the separation layer has a plurality of pixel openings, and the first electrodes are provided in each of the pixel openings in one-to-one correspondence.

In an exemplary embodiment of the present disclosure, the pixel opening is located in the support layer.

In an exemplary embodiment of the present disclosure, the display panel further includes:
an etching barrier layer, disposed on the side of the driving backplane same as the separation layer and is insulated from the first electrode; the first groove is penetrated in a direction perpendicular to the driving backplane, to expose at least a partial area of the etching barrier layer; a material of the etching barrier layer is different from a material of the support layer.

In an exemplary embodiment of the present disclosure, the etching barrier layer is formed of conductive material.

In an exemplary embodiment of the present disclosure, the first electrode includes a first conductive layer, a second conductive layer, a third conductive layer and a fourth conductive layer stacked in a direction away from the driving backplane; and
the fourth conductive layer is formed of same material and has same thickness as the etching barrier layer.

In an exemplary embodiment of the present disclosure, the first electrode further includes a fifth conductive layer, the fifth conductive layer is disposed on a surface of the fourth conductive layer away from the driving backplane, and is located within the pixel opening; and
the fifth conductive layer and the cutoff layer are same in material and thickness.

In an exemplary embodiment of the present disclosure, a distance, between orthogonal projections of the etching barrier layer and the fifth conductive layer of the first electrode adjacent to the etching barrier layer on the driving backplane, is greater than a distance, between orthogonal projections of the cutoff layer and the fifth conductive layer of the first electrode adjacent to the cutoff layer on the driving backplane.

In an exemplary embodiment of the present disclosure, orthographic projections of the cutoff layer and the etching barrier layer on the driving backplane are partly overlapped.

In an exemplary embodiment of the present disclosure, the cut groove is annular and is multiple in number, one cut groove is surrounded outside one of the first electrodes, and partial areas of the cut grooves surrounding two adjacent first electrodes are overlapped.

In an exemplary embodiment of the present disclosure, two side walls of the second groove are located between the two side walls of the first groove; and

a bump is formed in the support layer at an area corresponding to the etching barrier layer, and the two side walls of the second groove are located between boundaries of the bump.

In an exemplary embodiment of the present disclosure, the cut groove is annular and is multiple in number, one cut groove is surrounded outside one of the first electrodes, and two cut grooves distributed at intervals are disposed between two adjacent first electrodes.

In an exemplary embodiment of the present disclosure, the cutoff layer includes a planar part and a climbing part, the climbing part is an annular structure surrounding the first electrode and is protruded in a direction away from the driving backplane, the climbing part is located between the two side walls of the first groove; and the plat part is connected between each of the climbing parts; and
the etching barrier layers exposed by different second grooves are spaced apart, and an orthographic projection of the climbing part on the driving backplane at least partially overlapped with the etching barrier layer exposed by the corresponding second groove.

In an exemplary embodiment of the present disclosure, one second groove is formed by the climbing part and the first electrode surrounded by the climbing part.

In an exemplary embodiment of the present disclosure, in the cut groove and the first electrode surrounded by the cut groove, at least a partial area of an outer peripheral surface of the first electrode is exposed by the cut groove.

In an exemplary embodiment of the present disclosure, a material of at least one of the cutoff layer and the etching barrier layer is a transparent conductive material.

In an exemplary embodiment of the present disclosure, the light-emitting layer further includes a plurality of light-emitting sub-layers connected in series, and at least one of the light-emitting sub-layers is connected in series to an adjacent light-emitting sub-layer through a charge generation layer.

In an exemplary embodiment of the present disclosure, the second electrode is recessed at the cut groove to form a recessed area.

According to an aspect of the present disclosure, a method of manufacturing a display panel is provided, including:
forming a driving backplane;
forming a first electrode layer and a separation layer on one side of the driving backplane, wherein the first electrode layer includes a plurality of first electrodes distributed at intervals; the separation layer includes a support layer and a cutoff layer stacked in a direction away from the driving backplane; a material of the support layer is an insulating material and each of the first electrodes is exposed; an orthographic projection of the cutoff layer on the driving backplane and an orthographic projection of the first electrode on the driving backplane are spaced apart; the separation layer is configured with a cut groove located elsewhere of the first electrode, the cut groove includes a first groove located on the support layer and a second groove located on the cutoff layer, an orthographic projection of at least one side wall of the second groove on the driving backplane is located between orthographic projections of boundaries of two side walls of the first groove away from a surface of the driving backplane on the driving backplane;
forming light-emitting layer covering the separation layer and the first electrode; and
forming a second electrode covering the light-emitting layer.

According to an aspect of the present disclosure, a display device is provided, including the display panel according to any one of the above.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure. Obviously, the drawings in the following description are only some embodiments of the present disclosure. For those of ordinary skill in the art, other drawings can be obtained based on these drawings without exerting creative efforts.

FIG. 1 is a partial cross-sectional view of a display panel according to the first embodiment of the present disclosure.

FIGS. 2 to 6 are partial cross-sectional views of different steps of the first embodiment of the display panel of the present disclosure.

FIG. 7 is a partial cross-sectional view of a display panel according to the second embodiment of the present disclosure.

FIGS. 8 to 10 are partial cross-sectional views of different steps of the second embodiment of the display panel of the present disclosure.

FIG. 11 is a schematic diagram of a light-emitting unit in an embodiment of the display panel of the present disclosure.

### DETAILED DESCRIPTION

Example embodiments will now be described more fully with reference to the accompanying drawings. Example embodiments may, however, be embodied in various forms and should not be construed as limited to the embodiments set forth herein; rather, these embodiments are provided so that this disclosure will be thorough and complete and will fully convey the concepts of the example embodiments. To those skilled in the art. The same reference numerals in the drawings indicate the same or similar structures, and thus their detailed descriptions will be omitted. Furthermore, the drawings are merely schematic illustrations of the present disclosure and are not necessarily drawn to scale.

The terms “a”, “an”, “the”, “said” and “at least one” are used to indicate the presence of one or more elements/components/etc.; the terms “include” and “have” are used to indicate an open-ended inclusive and mean that there may be additional elements/components/etc. in addition to those listed; the terms “first”, “second”, “third” etc. are only used as a marker, not a limit on the number of its objects.

In related technology, Micro OLED (Micro Organic Light-Emitting Diode) display panel is a display panel developed in recent years, and it contains the Micro OLED light-emitting device usually having a size of less than 100 μm. The silicon-based OLED display panels are a relatively common one. The silicon-based OLED can not only realize active addressing of pixels, but also realize preparing CMOS circuits such as pixel circuits, timing control (TCON) circuits, over-current protection (OCP) circuits and the like on the silicon substrate through semiconductor manufacturing processes, which is beneficial to reduce the system volume and achieve lightweight.

Taking a silicon-based OLED display panel as an example, it may include a driving backplane and a light-emitting layer. The light-emitting functional layer is provided on one side of the driving backplane and includes a plurality of light-emitting devices. The light-emitting unit may include one or more series-connected OLED light-emitting devices, each light-emitting device includes a first electrode (anode), a light-emitting layer and a second electrode (cathode) sequentially stacked in a direction away from the driving backplane. By applying an electrical signal to the first electrode and the second electrode, the light-emitting layer can be driven to emit light. The specific light-emitting principle of the OLED light-emitting device will not be described in detail here.

In addition, the light-emitting layer of each light-emitting device can be directly evaporated through a fine mask (FMM). The light-emitting layers of each light-emitting device are spaced apart and emit light independently to achieve color display. However, due to the limitations of the fine mask manufacturing process, it is difficult to achieve high PPI (pixel density). Therefore, color display can also be achieved by combining monochromatic light or white light with a color film. That is, each light-emitting device shares the same continuous light-emitting layer. The light-emitting layer can emit white light or other monochromatic light. The color film layer has multiple filter areas corresponding to the light-emitting units one by one. One filter area and the corresponding light-emitting unit can form a sub-pixel, and multiple sub-pixels form a pixel. The colors of light that can be transmitted through different filter areas can be different, so that light emitted by different sub-pixels may be different in color, and the same pixel may include multiple sub-pixels with different colors. For example, a pixel may include three sub-pixels whose emitting colors are red, green, and blue. As a result, color display can be achieved using multiple pixels.

However, if the light-emitting layer has a continuous whole-layer structure, current leakage may easily occur between one light-emitting unit and surrounding light-emitting units, resulting in cross-color. For example: each light-emitting unit may include multiple light-emitting devices connected in series. Each light-emitting device of the same light-emitting unit shares a first electrode and a second electrode. There are multiple light-emitting sub-layers between the first electrode and the second electrode. The light-emitting sub-layers can be connected in series through the charge generation layer. Positive charges (holes) can be transferred between two adjacent light-emitting units through the charge generation layer. When the light-emitting unit corresponding to the red filter area in the color filter layer emits light, due to the influence of leakage, the light-emitting unit in the green filter area of the corresponding color filter layer may also be caused to emit light, resulting in reduction in the light-emitting purity of a single pixel and a reduction in the color gamut of the entire display panel.

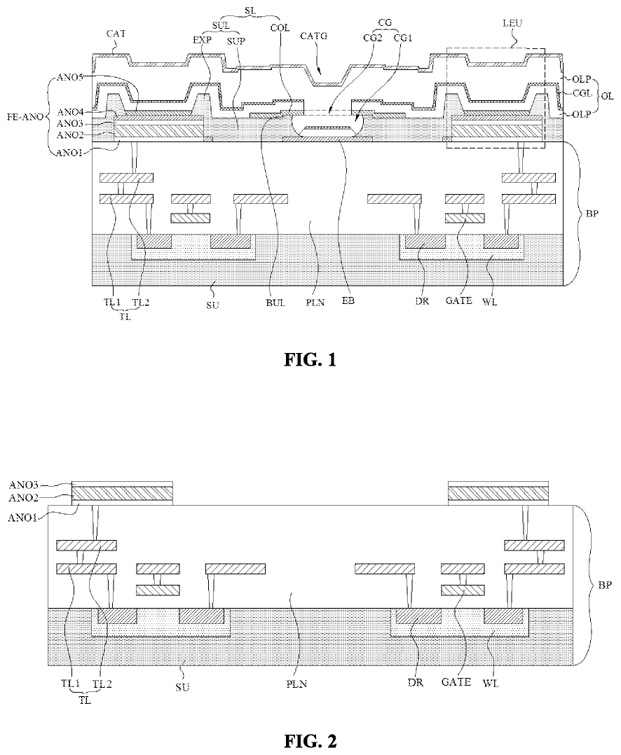

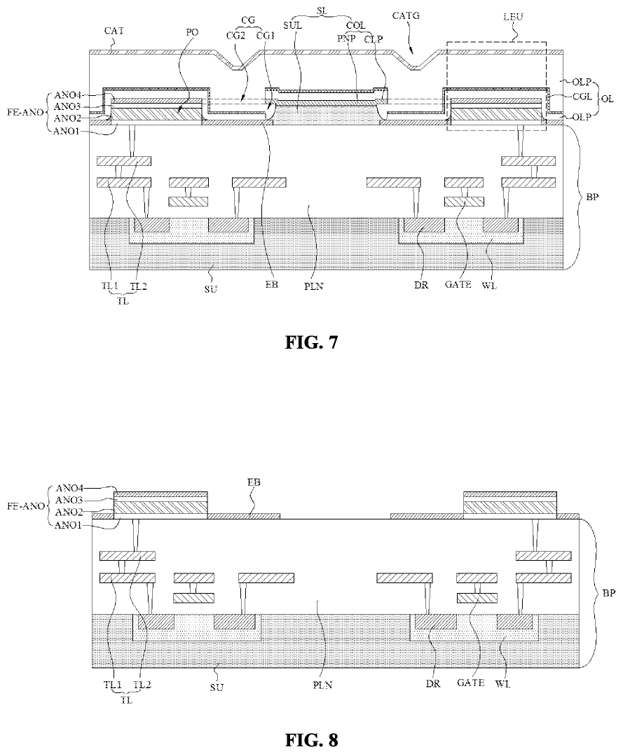

Embodiments of the present disclosure provide a display panel, as shown in FIGS. 1 and 7. The display panel may include a driving backplane BP, a first electrode layer FE, a separation layer SL, a light emitting layer OL, and a second electrode CAT, where:

The first electrode layer FE is provided on one side of the driving backplane BP and includes a plurality of first electrodes ANO distributed at intervals. The separation layer SL and the first electrode layer FE are provided on the same side of the driving backplane BP. The separation layer SL includes a support layer SUL and a cutoff layer COL stacked in a direction away from the driving backplane BP; the material of the support layer SUL is an insulating material, and each first electrode ANO is exposed; the orthographic projection of the cutoff layer COL on the driving backplane BP is spaced apart from the orthographic projection of the first electrode ANO on the driving backplane BP. The separation layer SL is provided with a cut groove CG located elsewhere of the first electrode ANO. The cut groove CG includes a first groove CG1 located at the support layer SUL and a second groove CG2 located at the cutoff layer COL. The orthographic projection of at least one side wall of the second groove CG2 on the driving back plate BP is located between the orthographic projections of the boundaries of the two side walls of the first groove CG1 away from the surface of the driving back plate BP on the driving back plate BP. The light-emitting layer OL covers the separation layer SL and the first electrode ANO. The second electrode CAT covers the light emitting layer OL.

In the display panel according to the embodiment of the present disclosure, any first electrode ANO and its corresponding light-emitting layer OL and second electrode CAT can form a light-emitting unit. The separation layer SL can separate each light-emitting unit. At the same time, the orthographic projection of at least one side wall of the second groove CG2 on the driving back plate BP is located between the orthographic projection of the boundaries of the two side walls of the first groove CG1 away from the surface of the driving back plate BP on the driving back plate BP, so that at least one side wall of the second groove CG2 is cantilevered on the first groove CG1, which can increase the difficulty for the light-emitting layer OL to continuously pass through the cut groove CG, cause the light-emitting layer OL to be thinned or even disconnected in the cut groove CG, therefore reducing the risk of mutual leakage between adjacent light-emitting units and improve the cross-color. In addition, the orthogonal projections of the cutoff layer COL and the first electrode ANO are distributed separately, which can disconnect the cutoff layer COL and the first electrode ANO and prevent the adjacent first electrode ANO from being short-circuited.

Hereinafter, the structure of the display panel to realize the display function of the present disclosure is explained in detail.

As shown in FIG. 1 and FIG. 7, the driving backplane BP may include a pixel area and a peripheral area. The peripheral area is located outside the pixel area and may be arranged around the pixel area. The driving backplane BP is used to form a driving circuit that drives the light-emitting unit LEU to emit light. The driving circuit may include a pixel circuit and a peripheral circuit, where:

The pixel circuit and light-emitting unit LEU can be multiple in number, and at least part of the pixel circuit is located in the pixel area. The pixel circuit can be a 2T1C, 4T2C, 6T1C or 7T1C pixel circuit, as long as it can drive the light-emitting unit LEU to emit light, there is no special limitation on its structure here. The number of pixel circuits is the same as the number of first electrodes ANO, and the pixel circuits are connected to the first electrodes ANO in one-to-one correspondence, so as to respectively control each light-emitting unit LEU to emit light. In the embodiment, nTmC means that a pixel circuit includes n transistors (indicated by the letter “T”) and m capacitors (indicated by the letter “C”). Of course, one same pixel circuit can also drive multiple light-emitting units LEU.

The peripheral circuit is located in the peripheral area and connected to the pixel circuit. The peripheral circuit may include a light emitting control circuit, a gate driving circuit, and a source driving circuit. In addition, it may also include a power supply circuit connected to the second electrode CAT for inputting a power signal to the second electrode CAT. The peripheral circuit can input signals to the first electrode ANO and the second electrode CAT through the pixel circuit, thereby causing the light-emitting unit LEU to emit light.

In some embodiments of the present disclosure, as shown in FIGS. 1 and 7, the driving backplane BP may include a substrate SU. The substrate SU may be a silicon substrate. The above-mentioned driving circuit may be formed on the silicon substrate through a semiconductor process. For example, both the pixel circuit and the peripheral circuit may include a plurality of transistors, and a well region WL may be formed in the silicon substrate through a doping process. The well region WL has two doped regions DR spaced apart. At the same time, take a well region WL as an example: a gate electrode GATE is provided on one side of the driving backplane BP, that is, the orthographic projection of the gate electrode GATE on the driving backplane BP is located between the two doped regions DR. The well region WL and the gate electrode GATE can form a transistor, the doped region DR of the well region WL is the first electrode and the second electrode of the transistor respectively, and the well region WL between the two doped regions DR is the channel region of the transistor.

The driving backplane BP may also include at least one wiring layer TL and a planar layer PLN. The wiring layer TL is provided on one side of the substrate SU. The planar layer PLN covers the wiring layer TL. At least one wiring layer TL is connected with the respective doped regions DR.

For example: As shown in FIG. 1 and FIG. 7, the number of wiring layers TL is two, and they are located in the planar layer PLN. For example, the wiring layer TL includes a first wiring layer TL1 and a second wiring layer TL2. The first wiring layer TL1 is provided on one side of the substrate SU, and a part of the planar layer PLN is provided between the first wiring layer TL1 and the substrate SU. The second wiring layer TL2 is provided on the side of the first wiring layer TL1 away from the substrate SU. The second wiring layer TL2 is separated from the first wiring layer TL1 by a part of the planar layer PLN, and at least a part area of the second wiring layer TL2 is connected to the first wiring layer TL1. The transistors are connected through respective wiring layers TL to form a drive circuit. The specific connection lines and wiring patterns depend on the circuit structure and are not specifically limited here.

Each wiring layer TL can be formed through a sputtering process. The material of the planar layer PLN can be silicon oxide, silicon oxynitride or silicon nitride, and is formed layer by layer through multiple deposition and polishing processes. That is to say, the planar layer PLN can be formed by stacking multiple insulating film layers.

As shown in FIG. 1, FIG. 7 and FIG. 11, the respective light-emitting units LEU are distributed in an array on one side of the driving backplane BP. For example, each light-emitting unit LEU is provided on the surface of the planar layer PLN away from the substrate SU. Each light-emitting unit LEU may include a first electrode ANO, a second electrode CAT, and a light-emitting layer OL located between the first electrode ANO and the second electrode CAT. Both the first electrode ANO and the second electrode CAT may be connected to the wiring layer TL. The driving signal is applied to the first electrode ANO by the driving backplane BP, and the power signal is applied to the second electrode CAT, thereby driving the light-emitting layer OL to emit light.

In order to realize color display, each light-emitting unit LEU can emit light of the same color, and cooperate with the color film layer located on the side of the second electrode CAT away from the driving backplane BP to achieve color display. In the embodiment of the present disclosure, such a color display scheme is illustrated as an example. Of course, each light-emitting unit LEU can also be made to emit light independently, and the light-emitting colors of different light-emitting units LEU can be different, thereby directly realizing color display.

In some embodiments of the present disclosure, as shown in FIGS. 1 and 7, a plurality of light-emitting units LEU may be formed by the first electrode layer FE, the separation layer SL, the light-emitting layer OL, and the second electrode CAT, where:

The first electrode layer FE is disposed on one side of the driving backplane BP. For example, the first electrode layer FE is disposed on the surface of the planar layer away from the substrate. The first electrode layer FE may include a plurality of first electrodes ANO distributed at intervals, and the orthographic projection of each first electrode ANO on the driving backplane BP is located in the pixel area, and the first electrode ANO is connected to the pixel circuit. One first electrode ANO is connected to one the pixel circuit, for example, the first electrode ANO can be connected to the second wiring layer.

The first electrode layer FE may have a single-layer or multi-layer structure, and its material is not particularly limited here. For example:

As shown in FIGS. 7 and 8, in some embodiments of the present disclosure, the first electrode ANO may include a first conductive layer ANO1, a second conductive layer ANO2, a third conductive layer ANO3 and a fourth conductive layer ANO4 sequentially stacked in a direction away from the driving backplane BP, wherein the first conductive layer ANO1 and the third conductive layer ANO3 can use the same metal material, for example, titanium, and the fourth conductive layer ANO4 can use transparent conductive materials such as ITO (indium tin oxide). The second conductive layer ANO2 can use a different metal material from the first conductive layer ANO1, the third conductive layer ANO3 and the fourth conductive layer ANO4, and the resistivity thereof is lower than those of the first conductive layer ANO1 and the third conductive layer ANO3, for example. The material of the second conductive layer ANO2 may be aluminum.

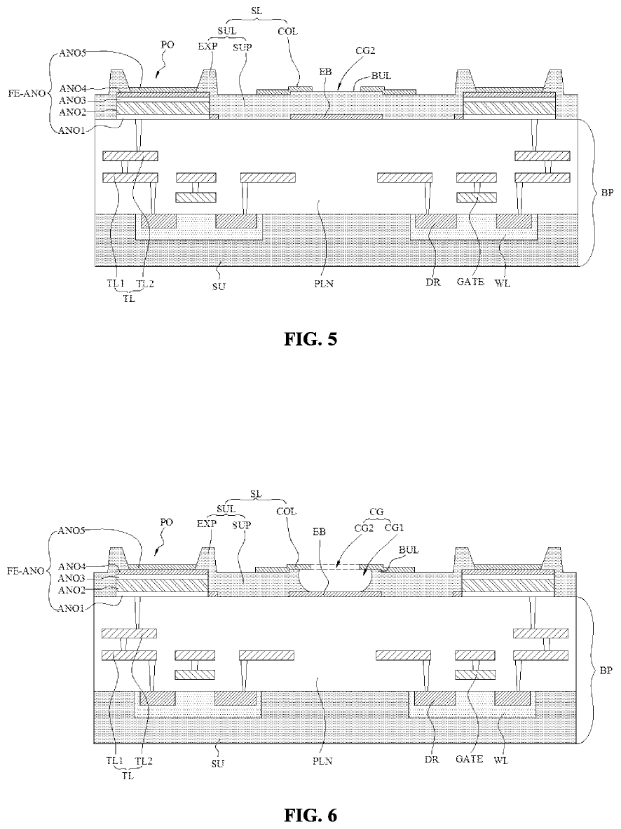

As shown in FIGS. 1 and 5, in other embodiments of the present disclosure, in addition to the above-mentioned first to fourth conductive layers ANO1 to ANO4, the first electrode ANO may also include a fifth conductive layer ANO5, which may be on the surface of the second conductive layer ANO2 away from the driving backplane BP, the material of the fifth conductive layer ANO5 can be the same as the fourth conductive layer ANO4. For example, the fourth conductive layer ANO4 and the fifth conductive layer ANO5 are both ITO (indium tin oxide). Of course, the material of the fifth conductive layer ANO5 may also be different from the material of the fourth conductive layer ANO4.

As shown in FIGS. 1 to 6, the separation layer SL and the first electrode layer FE are disposed on the same surface of the driving backplane BP, that is, the surface of the planar layer away from the substrate, and the separation layer SL exposes each first electrode ANO. Specifically, the separation layer SL may be provided with a plurality of pixel openings PO exposing each first electrode ANO.

The orthographic projection of any pixel opening PO on the driving backplane BP can be located within the first electrode ANO exposed by the pixel opening PO. That is to say, the pixel opening PO is not larger than the first electrode ANO exposed by the pixel opening PO. For example: the boundary of the pixel opening PO is located inside the boundary of the first electrode ANO exposed by the pixel opening PO, that is, the area of the pixel opening PO is smaller than the area of the first electrode ANO exposed by the pixel opening PO; alternatively, the boundary of the pixel opening PO can also coincide with the boundary of the first electrode ANO exposed by the pixel opening PO, or located outside the first electrode ANO, that is, the first electrode ANO may be located within the pixel opening PO.

The shape of the pixel opening PO can be a rectangle, a pentagon, a hexagon or other polygons, but not necessarily a regular polygon. The shape of the pixel opening PO can also be an ellipse or other shapes, which is not specifically limited here.

As shown in FIGS. 1 and 7, the light-emitting layer OL covers the separation layer SL and the first electrode ANO. The area where the light-emitting layer OL overlaps the first electrode layer FE is used to form a light-emitting unit LEU. That is to say, the respective light-emitting units LEU can share the same light-emitting layer OL, and the parts of the light-emitting layer OL located on different first electrodes ANO belong to different light-emitting units LEU. In addition, since each light-emitting unit LEU shares the light-emitting layer OL, different light-emitting units LEU emit the same color.

In some embodiments of the present disclosure, as shown in FIGS. 1 and 7, the light-emitting unit LEU may include a plurality of light-emitting devices connected in series, and each light-emitting unit LEU includes a first electrode ANO, a second electrode CAT, and a plurality of light-emitting sub-layers OLP between the first electrode ANO and the second electrode CAT, each light-emitting device of the same light-emitting unit LEU can share the same first electrode ANO and the same second electrode CAT, that is to say, the same one light-emitting unit LEU may have only one first electrode ANO and one second electrode CAT.

For example: As shown in FIGS. 1 and 7, the light-emitting layer OL may include multiple light-emitting sub-layers OLP serially connected in the direction away from the driving backplane BP. At least one light-emitting sub-layer OLP is connected in serial to the adjacent light-emitting sub-layer OLP through the charge generation layer. When an electrical signal is applied to the first electrode ANO and the second electrode CAT, each light-emitting sub-layer OLP can emit light, and different light-emitting sub-layers OLP can be used to emit light of different colors.

Further, as shown in FIG. 11, any light-emitting sub-layer OLP may include a hole injection layer HIL, a hole transport layer HTL, a light-emitting material layer EML, an electron transport layer ETL and an electron injection layer EIL distributed in a direction away from the driving backplane BP. The specific light-emitting principle will not be described in detail here. In the embodiment, the number of hole injection layer HIL, hole transport layer HTL, electron transport layer ETL and electron injection layer EIL is not specially limited here, and adjacent light-emitting sub-layers OLP may share one or more of the hole injection layer HIL, the hole transport layer HTL, the electron transport layer ETL and the electron injection layer EIL. At the same time, a charge generation layer CGL can be provided between at least two adjacent light-emitting sub-layers OLP, thereby connecting the two light-emitting sub-layers OLP in series.

In some embodiments of the present disclosure, as shown in FIG. 11, the light-emitting layer OL may include three light-emitting sub-layers OLP with different colors, namely a first light-emitting sub-layer OLP that emits red light, a second light-emitting sub-layer OLP that emits green light, and a third light-emitting sub-layer OLP that emits blue light. When the first light-emitting sub-layer OLP, the second light-emitting sub-layer OLP and the third light-emitting sub-layer OLP emit light at the same time, the light-emitting layer OL can emit white light. In the embodiment, the first light-emitting sub-layer OLP and the second light-emitting sub-layer OLP share the hole injection layer HIL, the hole transport layer HTL1, the electron transport layer ETL2 and the electron injection layer EIL, the light-emitting material layer G-EML of the second light-emitting sub-layer OLP is disposed on the surface of the emitting material layer R-EML first light-emitting sub-layer OLP away from the driving backplane BP, so that the first light-emitting sub-layer OLP and the second light-emitting sub-layer OLP are directly connected in series. The surface of the second light-emitting sub-layer OLP away from the driving backplane BP may be provided with a charge generation layer CGL. The third light-emitting sub-layer OLP shares the electron injection layer EIL with the first light-emitting sub-layer OLP and the second light-emitting sub-layer OLP. The hole injection layer HIL2 of the third light-emitting sub-layer OLP is located on the surface of the charge generation layer CGL away from the driving backplane BP. The hole transport layer HTL2 and the hole transport layer HTL3 of the third light-emitting sub-layer OLP are stacked on the side of the charge generation layer CGL away from the driving backplane BP. The charge generation layer CGL can connect the third light-emitting sub-layer OLP in series with the second light-emitting sub-layer OLP and the first light-emitting sub-layer OLP. In addition, a hole blocking layer HBL may be provided between the electron transport layer HYL and the light-emitting material layer BEML of the third light-emitting sublayer OLP.

The above structure of the light-emitting layer OL is only an illustration and does not constitute a limitation on its film layer. It may include only two light-emitting sub-layers OLP, or may include more, or include only one light-emitting sub-layer OLP, as long as it can be used with the color film layer to achieve color display.

As shown in FIGS. 1 and 7, the second electrode CAT covers the light-emitting layer OL, and the orthographic projection of the second electrode CAT on the driving backplane BP can cover the pixel area and extend into the peripheral area. Each light-emitting unit LEU may share the same second electrode CAT. When the voltage difference between the second electrode CAT and the first electrode ANO reaches a voltage difference that enables the light-emitting layer OL to emit light, the light-emitting layer OL can emit light. Therefore, the voltages of the power signal input to the second electrode CAT and the driving signal input to the first electrode ANO can be controlled to control the light emitting layer OL to emit light.

The display panel may also include a color filter layer, which may be disposed on the side of the second electrode CAT away from the driving backplane BP, and include a plurality of filter parts, with each first electrode ANO and each filter part being disposed in one-to-one correspondence in the direction perpendicular to the driving backplane BP, that is, the orthographic projection of a filter part on the driving backplane BP and a first electrode ANO at least partially overlap. The respective filter parts include filter parts of at least three color, for example, a filter part that can transmit red light, a filter part that can transmit green light, and a filter part that can transmit blue light. After the light emitted by each light-emitting unit LEU is filtered by the light-emitting unit LEU, the monochromatic light of different colors may be obtained, thereby realizing color display. In the embodiment, a light-emitting unit LEU and its corresponding light-emitting unit can form a sub-pixel. The light-emitting color of any sub-pixel is the color of the light transmitted through the filter part thereof. Multiple sub-pixels can form one pixel, and the light-emitting colors of respective sub-pixels of the same pixel are different.

The shape of the orthographic projection of the filter part on the planar layer can be the same as the shape of the pixel opening PO of the separation layer SL, and the orthographic projection of each pixel opening PO on the planar layer is located within the orthographic projection of each filter part on the planar layer in one-to-one correspondence.

The color filter layer may also include a light-shielding portion that separates the filter part. The light-shielding portion is opaque and blocks the area between the two light-emitting units LEU. The filter part can be directly provided with a light-shielding material and disposed alternately with the filter part; or, in some embodiments of the present disclosure, adjacent filter parts can be stacked in a region corresponding to two adjacent light-emitting units LEU, moreover, the colors of light transmitted by the two are different, making the stacked area opaque.

In addition, in some embodiments of the present disclosure, in order to improve the brightness of the picture on the basis that the light-emitting layer OL emits white light, the color filter layer may also include a transparent part. In the direction perpendicular to the substrate, a transparent part may be disposed opposite to a light-emitting units LEU, such that the color film layer can also transmit white light and increase the brightness by the white light.

In order to improve the light extraction efficiency, a light extraction layer can be covered on the side of the second electrode CAT away from the driving backplane BP to increase the brightness. Furthermore, the light extraction layer can directly cover the surface of the second electrode CAT away from the driving backplane BP.

In order to facilitate the connection between the second electrode CAT and the driving circuit, in some embodiments of the present disclosure, the first electrode layer FE also includes an adapter ring, and the orthographic projection of the adapter ring on the driving backplane BP is located in the peripheral area. The adapter ring can be connected to the peripheral circuit and surrounded outside the pixel area. The second electrode CAT can be connected to the adapter ring, so that the second electrode CAT can be connected to the peripheral circuit through the adapter ring, so that the peripheral circuit applies a driving signal to the second electrode CAT. The pattern of the transfer ring may be the same as the pattern of the first electrode ANO in the pixel area, so as to improve the uniformity of the pattern of the first electrode layer FE.

In some embodiments of the present disclosure, the display panel of the present disclosure may further include a first encapsulation layer, which may be disposed on a side of the second electrode CAT away from the driving backplane BP and located between the color filter layer and the second electrode CAT, to block the penetration of external water and oxygen. The first encapsulation layer may be a single-layer or multi-layer structure. For example, the first encapsulation layer may include a first encapsulation sub-layer, a second encapsulation sub-layer and a third encapsulation sub-layer that are sequentially stacked in a direction away from the driving backplane BP. In the embodiment, the materials of the first encapsulation sub-layer and the second encapsulation sub-layer can be inorganic insulating materials such as silicon nitride and silicon oxide, and the second encapsulation sub-layer can be formed using an ALD (Atomic layer deposition) process; the material of the third encapsulation sub-layers can be organic materials, which can be formed using MLD (Molecular Layer Deposition) process. Of course, the first encapsulation layer can also adopt other structures, and the structure of the first encapsulation layer is not specifically limited here.

In addition, in some embodiments of the present disclosure, the display panel of the present disclosure can also include a transparent cover plate, which can cover the side of the color filter layer away from the driving backplane BP. The transparent cover plate can be a single-layer or multi-layer structure, and its material is not specifically limited here.

In some embodiments of the present disclosure, the display panel of the present disclosure may further include a second encapsulation layer, which may cover the surface of the color filter layer away from the driving backplane BP to achieve planarization and facilitate the covering of the transparent cover, and may improve the encapsulation effect and further block water and oxygen. The second encapsulation layer may have a single-layer or multi-layer structure, and may include inorganic materials such as silicon nitride and silicon oxide, or organic materials. The structure of the second encapsulation layer is not specifically limited here.

Hereinafter, a detailed description of the solution of the display panel of the present disclosure to solve the color cross-color problem is described in detail.

Combined with the above analysis of related technologies, since respective light-emitting units LEU share the light-emitting layer OL, carriers (such as holes) of one light-emitting unit LEU may move to other light-emitting units LEU through the charge generation layer and the like, especially toward the adjacent light-emitting unit LEU, i.e., the leakage occurs, affecting the purity of the light emission. To this end, as shown in FIGS. 1 and 7, a cut groove CG can be provided in the separation layer SL. Due to the structural limitations of the cut groove CG, when the light-emitting layer OL is formed, it is difficult to be continuous within the cut groove CG, thus it is easy to be thinned or even disconnect to prevent carriers from moving between the light-emitting units LEU, and in turn prevent the cross-color due to leakage.

To this end, the cut groove CG can include a first groove CG1 and a second groove CG2 connected in a direction away from the driving backplane BP. The width of the first groove CG1 is greater than the width of the second groove CG2, that is, the distance between the two side walls of the first groove CG1 is smaller than the distance between the two side walls of the second groove CG2, so that the orthographic projection of at least one side wall of the second groove CG2 on the driving backplane BP is located between the orthographic projections on the driving backplane BP of the boundaries of the two side walls of the first groove CG1 away from the driving backplane BP, so that at least one side wall of the second groove CG2 is cantilevered, so that the light-emitting layer OL is thinned or even disconnected in the cut groove CG.

The side walls of the first groove CG1 and the second groove CG2 are not limited to spliced smooth curved surfaces or planes. They can be of any shape, which is specifically limited by the etching process, as long as the first groove CG1 and the second groove CG2 can be formed. For example, as the etching depth increases, the etching degree gradually weakens, and the width of the first groove CG1, that is, the distance between the two side walls of the first groove CG1, can be reduced.

Hereinafter, the specific implementation of the cut groove CG is exemplarily described.

As shown in FIGS. 1 and 7, in some embodiments of the present disclosure, the separation layer SL may include a support layer SUL and a cutoff layer COL.

The support layer SUL and the first electrode ANO are disposed on the same surface of the driving backplane BP, and each first electrode ANO is exposed. That is, the pixel opening PO can be disposed at the support layer SUL, and the support layer SUL is an insulating material, and its material can be silicon nitride, silicon oxide and other insulating materials. The cutoff layer COL can be disposed on the surface of the support layer SUL away from the driving backplane BP, and the cutoff layer COL and the first electrode ANO can be disposed at intervals so that they are insulated.

As shown in FIG. 1 and FIG. 7, the cut groove CG may include a first groove CG1 located in the support layer SUL and a second groove CG2 located in the cutoff layer COL. The first groove CG1 and the second groove CG2 are penetrated in the direction perpendicular to the driving backplane BP. At least one side wall of the second groove CG2 is located between the two side walls of the first groove CG1, so that at least part of the cutoff layer COL extends between the two side walls of the first groove CG1 and is cantilevered. At least part of the film layer of the light-emitting layer OL is difficult to form on the surface of the cantilevered portion away from the driving backplane BP, so it is easy to disconnect. For example: the charge generation layer and its light-emitting sub-layer OLP on the side close to the driving backplane BP can be disconnected in the cut groove CG, thereby preventing leakage between adjacent light-emitting units LEU through the charge generation layer, and preventing crosstalk.

The light-emitting layer OL is recessed at the cut groove CG, so that the second electrode CAT is recessed at the cut groove CG to form a recessed area CATG, that is, the area of the second electrode CAT corresponding to the cut groove CG is recessed toward the area corresponding to the first electrode ANO, and the recessed depth is limited by the depth of the cut groove CG and is not specifically limited here.

As shown in FIGS. 1 and 7, the material of the cutoff layer COL is different from the support layer SUL, so that the second groove CG2 and the first groove CG1 can be formed independently to prevent the second groove CG2 from being affected when the first groove CG1 is formed. The material of the cutoff layer COL can be a transparent conductive material, such as indium tin oxide (ITO). Of course, it can also be other metal oxides or metals. Of course, it can also be an insulating material, as long as it is different from the material of the support layer SUL, and they can be slotted separately.

Taking the material of the cutoff layer COL being indium tin oxide as an example: the support layer SUL and the cutoff layer COL made of indium tin oxide can be formed in sequence; then a second groove CG2 is opened on the cutoff layer COL through an etching process; then, the first groove CG1 is formed by an etching process in the area where the support layer SUL is exposed by the second groove CG2. Specifically, wet etching can be used, and the used etching liquid has an etching effect on the support layer SUL, but does not have an etching effect on the cutoff layer COL. Through the etching effect, the first groove CG1 can be formed on the support layer SUL by the etching liquid. As the etching process proceeds, the etched area will extend to the area covered by the cutoff layer COL, thereby causing the cutoff layer COL to be partially cantilevered, to obtain the above cut groove CG.

In order to easily limit the depth of the cut groove CG and improve the uniformity of the depth of the cut groove CG, an etching barrier layer EB can be disposed at the bottom of the cut groove CG. Through the etching barrier layer EB, for example:

As shown in FIGS. 1 and 7, in some embodiments of the present disclosure, the etching barrier layer EB may be disposed on the same side of the driving backplane BP as the separation layer SL, and may be spaced apart from the first electrode ANO, thereby being insulated from the first electrode ANO. The etching barrier layer EB is located within the range covered by the separation layer SL and corresponds to the first groove CG1, that is, the orthographic projection of the first groove CG1 on the driving backplane BP at least partially coincides with the etching barrier layer EB. At the same time, the first groove CG1 can penetrate in the direction perpendicular to the driving backplane BP, that is, the depth of the second groove CG2 is the same as the thickness of the support layer SUL, so that the first groove CG1 exposes at least part of the etching barrier layer EB. That is to say, the area of the surface of the etching barrier layer EB away from the driving backplane BP that is exposed by the first groove CG1 serves as the bottom surface of the first groove CG1.

In addition, the material of the etching barrier layer EB is different from the material of the support layer SUL. When forming the first groove CG1 of the cut groove CG, the etching liquid can only remove the material of the support layer SUL, but not the etching barrier layer EB, so that the depth of each first groove CG1 is the same.

As shown in FIGS. 1 and 7, in some embodiments of the present disclosure, part of the light-emitting layer OL located in the cut groove CG is stacked on the etching barrier layer EB. In order to further reduce crosstalk, the leakage current between two adjacent light-emitting units LEU can be conducted out. To this end, the etching barrier layer EB can be made of a conductive material such as metal or conductive metal oxide. For example, the material of the barrier layer can be indium tin oxide. At the same time, the barrier layer can be connected to the peripheral area of the driving backplane BP and grounded, so that the leakage between two adjacent light-emitting units LEU can be conducted out. Even if the light-emitting layer OL is not completely disconnected in the cut groove CG, the leakage can be conducted out by the etching barrier layer EB to improve crosstalk.

The orthographic projections of the cutoff layer COL and the etching barrier layer EB on the driving backplane BP partially overlaps. In other words, the cutoff layer COL blocks part of the etching barrier layer EB, which is beneficial to the formation of the cut groove CG.

The cut groove CG can be in the shape of a ring, which refers to a hollow closed structure extending continuously along the circumferential direction of the first electrode ANO. The outline shape of the ring can be circular, polygonal or other shapes, and is not specifically limited here. For example, the shape of the cut groove CG may be the same as the shape of the first electrode ANO. The cut groove CG can be multiple in number, and one cut groove CG surrounds outside a first electrode ANO. At the same time, some areas of the cut grooves CG surrounding two adjacent first electrodes ANO overlap; or, there are two cut grooves CG distributed at intervals between the two adjacent first electrodes ANO. The following is a detailed description of these two types of cut groove CG.

### Embodiment 1

As shown in FIGS. 1 to 6, each cut groove CG surrounds each electrode in one-to-one correspondence, and the partial areas of the cut groove CG surrounding the two adjacent first electrodes ANO overlap. In other words, one same cut groove CG can be used for surrounding a plurality of first electrodes ANO. For example, the shape of the cut groove CG is a polygon, and the two cut grooves CG surrounding the two adjacent first electrodes ANO can share the same side of the polygon, that is, the two cut grooves CG partially overlap. In the cross-section shown in FIG. X, there is only one cut groove CG between two adjacent first electrodes ANO, which is the overlapping part of the two cut grooves CG.

The two side walls of the second groove CG2 are located between the two side walls of the first groove CG1. That is to say, the portion of the cutoff layer COL between the two adjacent first electrodes ANO that is located on both sides of the second groove CG2 blocks the partial area of the first groove CG1, which makes the width of the second groove CG2 smaller than the width of the first groove CG1, which can improve the effect of cutting off the light-emitting layer OL.

The etching barrier layer EB is located between two adjacent first electrodes ANO and is spaced apart from the first electrode ANO. The etching barrier layer EB is exposed by the first groove CG1, and the bottom edges of both side walls of the first groove CG1 are located within the boundaries of the etching barrier layer EB.

The first groove CG1 is located on an etching barrier layer EB, and the bottom edges of both side walls of the first groove CG1 are located within the boundary of the etching barrier layer EB, thereby limiting the depth of the first groove CG1 to the greatest extent. At the same time, as shown in FIGS. 1, 4 to 6, due to the existence of the etching barrier layer EB, the support layer SUL forms a bump BUL in the area corresponding to the etching barrier layer EB, that is, the surface of the support layer SUL away from the driving backplane BP is raised in the area corresponding to the etching barrier layer EB. The cutoff layer COL can extend to the surface of the bump BUL away from the driving backplane BP, so that the two side walls of the second groove CG2 are located within the boundary of the bump BUL.

As shown in FIGS. 4 to 6, the boundary of the pixel opening PO is located inside the boundary of the exposed first electrode ANO, and the pixel opening PO is located on the support layer SUL. That is to say, the support layer SUL can extend to the surface of the first electrode ANO away from the driving backplane BP to form the extension part EXP. The extension part EXP is a ring structure and is used to surround the pixel. For example, the support layer SUL may include a support part SUP and an extension part EXP. The support part SUP and the first electrode ANO are located on the same side of the driving backplane BP and each first electrode ANO is separated; the extension part EXP may be formed by the support part SUP extending to the surface of the first electrode ANO away from the driving backplane BP. Each first electrode ANO may be provided with an extension part EXP, and each pixel opening PO is provided in each extension part EXP in one-to-one correspondence. At the same time, the thickness of the support part SUP is not greater than the first electrode ANO, so that the surface of the support part SUP away from the driving back plate BP is no higher than the surface of the first electrode ANO away from the driving back plate BP, and the extension part EXP is located on the side of the support part SUP away from the driving backplane BP. The light-emitting layer OL can be raised through the extension part EXP, which is beneficial to thinning or even cutting off the light-emitting layer OL, thus improving the cross-color problem. Based on FIG. 1, a light-emitting sub-layer OLP and the charge generation layer CGL of the light-emitting layer OL are cut off, while the light-emitting sub-layer OLP on the side of the charge generation layer CGL away from the driving backplane BP is only recessed at the cut groove CG but is not cut off.

As shown in FIGS. 1 to 6, the first electrode ANO includes a first conductive layer ANO1 to a fifth conductive layer ANO5, wherein the material of the fourth conductive layer ANO4 is the same as the material of the etching barrier layer EB, and the thicknesses of the both are also the same, so that after forming the first conductive layer ANO1, the second conductive layer ANO2 and the third conductive layer ANO3 of the first electrode ANO, the fourth conductive layer ANO4 and the etching barrier layer EB can be formed simultaneously. At the same time, the fifth conductive layer ANO5 can be located in the pixel opening PO, that is, the fifth conductive layer ANO5 is located in the range surrounded by the extension part EXP, and the fifth conductive layer ANO5 can be made of the same material and thickness as the cutoff layer COL of the separation layer SL, so that after the support layer SUL is formed, the fifth conductive layer ANO5 and the cutoff layer COL can be formed simultaneously.

The distance between the orthographic projections of the etching barrier layer EB and the fifth conductive layer ANO5 of its adjacent first electrode ANO on the driving backplane BP is greater than the distance between the orthographic projections of the cutoff layer COL and the fifth conductive layer ANO5 of its adjacent first electrode ANO on the driving backplane BP. That is to say, in the direction parallel to the driving backplane BP, the distance between the etching barrier layer EB and the first electrode ANO is greater than the distance between the cutoff layer COL and the first electrode ANO, which is beneficial to increasing the distance between the etching barrier layer EB and the first electrode ANO, and preventing short circuit.

### Embodiment 2

As shown in FIGS. 2, 7 to 10, each cut groove CG surrounds each electrode in one-to-one correspondence, and there are two cut groove CGs distributed at intervals between two adjacent first electrodes ANO. That is to say, the cut grooves CG around different first electrodes ANO do not overlap. To avoid that the width of the cut groove CG is too small so that the light-emitting layer OL cannot enter the cut groove CG, it is required to ensure that the cut groove CG has a certain width. However, since the cut grooves CG between two adjacent first electrodes ANO do not overlap, therefore, the cut groove is made CG as close as possible to the first electrode ANO.

As shown in FIG. 7, for example, the cut groove CG can expose at least part of the outer peripheral surface of the first electrode ANO surrounded by the cut groove CG, and the outer peripheral surface of the first electrode ANO can serve as one side wall of the first groove CG1 and the second groove CG2 surrounding the first electrode ANO, the other side wall of the second groove CG2 is located between the two side walls of the first groove CG1. That is to say, in order to ensure the width of the cut groove CG, only one side wall of the second groove CG2 may be located between the two side walls of the first groove CG1. Further, the thickness of the support layer SUL is not greater than the thickness of the first electrode ANO, that is, the surface of the support layer SUL away from the driving backplane BP is not higher than the surface of the first electrode ANO away from the driving backplane BP. The first groove CG1 is located at the support layer SUL, and the outer peripheral surface of the first electrode ANO is a side wall of the first groove CG1 surrounding the first electrode ANO. Of course, the side wall of the first groove CG1 may not be perpendicular to the driving backplane BP, so that the support layer SUL can cover at most part of the outer peripheral surface of the first electrode ANO, thus forming the side wall of the first groove CG1 together with the outer peripheral surface of the first electrode ANO. That is, the pixel opening PO is located at the support layer SUL, and the boundary of the pixel opening PO coincides with the boundary of the exposed first electrode ANO. There is no support layer SUL on the surface of the first electrode ANO away from the driving backplane BP. The second groove CG2 can be formed by the cutoff layer COL and the outer peripheral surface of the first electrode ANO. The cutoff layer COL can extend from the area of the support layer SUL where the first groove CG1 is not provided to between the two side walls of the first groove CG1, thereby blocking partial area of the first groove CG1, to thin or even cut off the light-emitting layer OL.

The first groove CG1 is located on an etching barrier layer EB, and the bottom edges of both side walls of the first groove CG1 are located inside the boundary of the etching barrier layer EB, thereby limiting the depth of the first groove CG1 to the greatest extent. At the same time, due to the existence of the etching barrier layer EB, the support layer SUL when the first groove CG1 is not opened forms a bump BUL corresponding to the area of the etching barrier layer EB, and the cutoff layer COL is extended to the surface of the bump away from the driving backplane BP to form a climbing part CLP. The cutoff layer COL other than the bump BUL is a planar part PNP. The climbing part CLP is an annular structure surrounding the first electrode ANO, and due to the existence of the bump BUL, it is protruded to the direction away from the driving back plate BP. After the first groove CG1 is formed, the area of the support layer SUL corresponding to the bump BUL is removed, and the climbing part CLP is located between the two side walls of the first groove CG1, and one climbing part CLP and the outer peripheral surface of the first electrode ANO surrounded by the climbing part CLP forms a second groove CG2, and the planar part PNP is the area connected between the climbing parts CLP in the cutoff layer COL. In addition, the etching barrier layers EB exposed by different second groove CG2 are spaced apart, and the orthographic projection of the climbing part CLP on the driving backplane BP at least partially overlaps with the etching barrier layer EB exposed by the corresponding second groove CG2.

Based on FIG. 7, a light-emitting sub-layer OLP and the charge generation layer CGL of the light-emitting layer OL are cut off, while the light-emitting sub-layer OLP on the side of the charge generation layer CGL away from the driving backplane BP is only recessed at the cut groove CG but is not cut off.

The first electrode ANO includes first conductive layer ANO1 to fourth conductive layer ANO4, wherein the material of the fourth conductive layer ANO4 is the same as the material of the etching barrier layer EB, and the thickness of the two is also the same. For example: the material of the fourth conductive layer ANO4 and the material of the etching barrier layer EB are both indium tin oxide. After forming the first conductive layer ANO1, the second conductive layer ANO2 and the third conductive layer ANO3 of the first electrode ANO, the fourth conductive layer ANO4 and the etching barrier layer EB may be formed simultaneously. At the same time, the material of the cutoff layer COL can be indium tin oxide, so that the cutoff layer COL can be formed separately after the support layer SUL is formed.

An embodiment of the present disclosure also provides a manufacturing method of a display panel. The display panel can be the display panel of any of the above embodiments, and its structure will not be described in detail here. The manufacturing method can include step S110-step S140.

In step S110, a driving backplane is formed.

In step S120, a first electrode layer and a separation layer are formed on one side of the driving backplane. The first electrode layer includes a plurality of first electrodes distributed at intervals; the separation layer includes a support layer and a cutoff layer laminated along a direction away from the driving backplane; the material of the support layer is an insulating material and respective first electrodes are exposed; the orthographic projection of the cutoff layer on the driving backplane and the orthographic projection of the first electrode on the driving backplane are distributed at intervals; the separation layer is provided with a cut groove located elsewhere the first electrode, and the cut groove includes a first groove located at the support layer and a second groove located at the separation layer; and the orthographic projection of at least one side wall of the second groove on the driving back plate is located between the orthographic projections of the boundaries of the two side walls of the first groove away from the surface of the driving backplane on the driving backplane.

In step S130: a light-emitting layer covering the separation layer and the first electrode is formed, and the light-emitting layer is disconnected in the cut groove.

In step S140: a second electrode covering the light-emitting layer is formed.

In some embodiments of the present disclosure, as shown in FIGS. 1 to 6, for the display panel in the first embodiment above, step S120 may include step S1210 to step S1250.

In step S1210: a plurality of first conductors distributed in an array are formed on one side of the driving backplane.

As shown in FIG. 2, the first conductor may include a first conductive layer, a second conductive layer and a third conductive layer stacked in sequence. The first conductive layer, the second conductive layer and the third conductive layer are the first conductive layer, the second conductive layer and the third conductive layer of the first electrode.

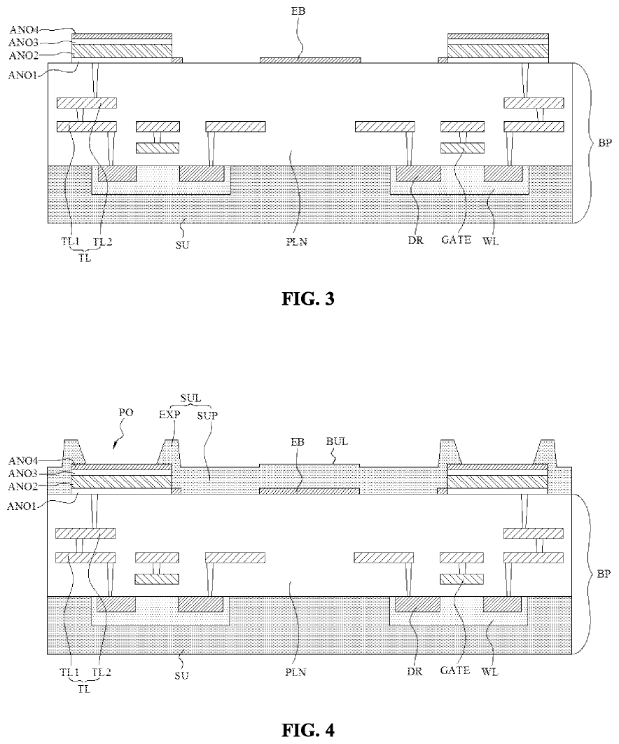

In step S1220: a fourth conductive layer and an etching barrier layer are formed simultaneously. As shown in FIG. 3.

In step S1230: a support layer that separates each first conductor is formed.

As shown in FIG. 4, the support layer at this time is in a state where the first groove is not opened at the support layer.

In step S1240: a cutoff layer is formed on the surface of the support material layer away from the driving backplane, and the cutoff layer has a second groove. As shown in FIG. 5.

In step S1250: the support material layer is etched along the second groove toward the driving backplane until the etching barrier layer is exposed to obtain the first groove, thereby obtaining the support layer. As shown in FIG. 6.

In some embodiments of the present disclosure, as shown in FIGS. 2 and 7 to 10, for the display panel in the second embodiment above, step S120 may include step S1201 to step S1202.

In step S1201: a plurality of first conductors distributed in an array are formed on one side of the driving backplane.

As shown in FIG. 2, the first conductor may include a first conductive layer, a second conductive layer and a third conductive layer stacked in sequence. The first conductive layer, the second conductive layer and the third conductive layer are the first conductive layer, the second conductive layer and the third conductive layer of the first electrode.

In step S1202: a fourth conductive layer and an etching barrier layer are formed simultaneously. As shown in FIG. 8.

In step S1203: a support layer covering each first conductor is formed.

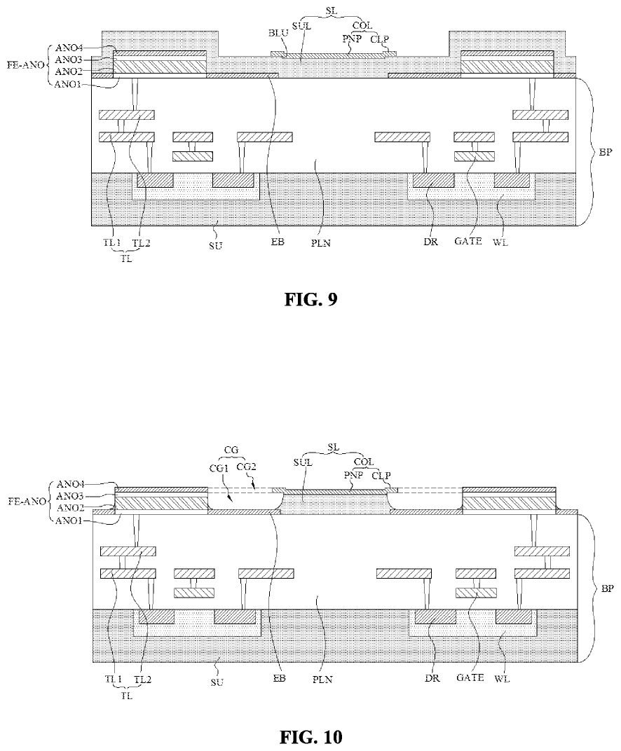

As shown in FIG. 9, the support layer at this time is a continuous film layer covering each first conductor at the same time.

In step S1204: a cutoff layer is formed on the surface of the support layer away from the driving backplane. As shown in FIG. 9.

The cutoff layer is located on the surface of the support material layer away from the driving backplane and has a second groove. The fifth conductive layer and the aforementioned first conductive layer, second conductive layer, third conductive layer and fourth conductive layer form the first electrode.

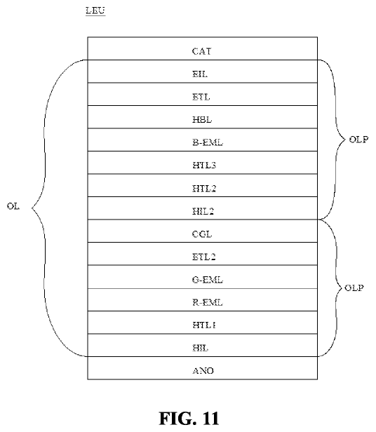

In step S1205: the support material layer is etched along the second groove toward the driving backplane until the etching barrier layer is exposed to obtain the first groove, thereby obtaining the support layer. As shown in FIG. 10.

Since the details of the structures involved in each step of the above manufacturing method have been described in detail in the embodiment of the display panel above, their details and beneficial effects will not be described in detail here.

It should be noted that although the various steps of the manufacturing method in the present disclosure are described in a specific order in the drawings, this does not require or imply that these steps must be performed in this specific order, or that all of the steps shown must be performed to achieve the desired results. Additionally or alternatively, certain steps may be omitted, multiple steps may be combined into one step for execution, and/or one step may be divided into multiple steps for execution, etc.

Embodiments of the present disclosure also provide a display device, which may include the display panel of any of the above embodiments. The specific structure and beneficial effects of the display panel have been described in detail in the embodiment of the display panel above, and will not be described in detail here. The display device of the present disclosure can be used in electronic devices with image display functions such as mobile phones, tablet computers, and televisions, which will not be listed here.

Other embodiments of the disclosure will be readily apparent to those skilled in the art from consideration of the specification and practice of the invention disclosed herein. This application is intended to cover any variations, uses, or adaptations of the disclosure that follow the general principles of the disclosure and include common knowledge or customary technical means in the technical field that are not disclosed in the disclosure. It is intended that the specification and examples be considered as exemplary only, with a true scope and spirit of the disclosure being indicated by the appended claims.

1. A display panel, comprising:
a driving backplane;
a first electrode layer, disposed on one side of the driving backplane and comprising a plurality of first electrodes distributed at intervals;
a separation layer, disposed on the side of the driving backplane same as the first electrode layer; wherein the separation layer comprises a support layer and a cutoff layer stacked in a direction away from the driving backplane; a material of the support layer is an insulating material and each of the first electrodes is exposed; an orthographic projection of the cutoff layer on the driving backplane and an orthographic projection of the first electrode on the driving backplane are spaced apart; the separation layer is configured with a cut groove located elsewhere of the first electrode, the cut groove comprises a first groove located on the support layer and a second groove located on the cutoff layer, an orthographic projection of at least one side wall of the second groove on the driving backplane is located between orthographic projections of boundaries of two side walls of the first groove away from a surface of the driving backplane on the driving backplane;
a light-emitting layer, covering the separation layer and the first electrode; and
a second electrode, covering the light-emitting layer.

2. The display panel according to claim 1, wherein the separation layer comprises a plurality of pixel openings exposing each of the first electrodes, and boundaries of each pixel opening are located inside boundaries of the first electrodes exposed by the pixel opening.

3. The display panel according to claim 1, wherein the separation layer has a plurality of pixel openings, and the first electrodes are provided in each of the pixel openings in one-to-one correspondence.

4. The display panel according to claim 2- or 3, wherein the pixel opening is located in the support layer.

5. The display panel according to claim 4, wherein the display panel further comprises:
an etching barrier layer, disposed on the side of the driving backplane same as the separation layer and is insulated from the first electrode; the first groove is penetrated in a direction perpendicular to the driving backplane, to expose at least a partial area of the etching barrier layer; a material of the etching barrier layer is different from a material of the support layer.

6. The display panel according to claim 5, wherein the etching barrier layer is formed of conductive material.

7. The display panel according to claim 6, wherein the first electrode comprises a first conductive layer, a second conductive layer, a third conductive layer and a fourth conductive layer stacked in a direction away from the driving backplane; and
the fourth conductive layer is formed of same material and has same thickness as the etching barrier layer.

8. The display panel according to claim 7, wherein the first electrode further comprises a fifth conductive layer, the fifth conductive layer is disposed on a surface of the fourth conductive layer away from the driving backplane, and is located within the pixel opening; and
the fifth conductive layer and the cutoff layer are same in material and thickness.

9. The display panel according to claim 6, wherein a distance, between orthogonal projections of the etching barrier layer and the fifth conductive layer of the first electrode adjacent to the etching barrier layer on the driving backplane, is greater than a distance, between orthogonal projections of the cutoff layer and the fifth conductive layer of the first electrode adjacent to the cutoff layer on the driving backplane.

10. The display panel according to claim 5, wherein orthographic projections of the cutoff layer and the etching barrier layer on the driving backplane are partly overlapped.

11. The display panel according to claim 7, wherein the cut groove is annular and is multiple in number, one cut groove is surrounded outside one of the first electrodes, and partial areas of the cut grooves surrounding two adjacent first electrodes are overlapped.

12. The display panel according to claim 11, wherein two side walls of the second groove are located between the two side walls of the first groove; and
a bump is formed in the support layer at an area corresponding to the etching barrier layer, and the two side walls of the second groove are located between boundaries of the bump.

13. The display panel according to claim 8, wherein the cut groove is annular and is multiple in number, one cut groove is surrounded outside one of the first electrodes, and two cut grooves distributed at intervals are disposed between two adjacent first electrodes.

14. The display panel according to claim 13, wherein the cutoff layer comprises a planar part and a climbing part, the climbing part is an annular structure surrounding the first electrode and is protruded in a direction away from the driving backplane, the climbing part is located between the two side walls of the first groove; and the plat part is connected between each of the climbing parts; and
the etching barrier layers exposed by different second grooves are spaced apart, and an orthographic projection of the climbing part on the driving backplane at least partially overlapped with the etching barrier layer exposed by the corresponding second groove.

15. The display panel according to claim 14, wherein one second groove is formed by the climbing part and the first electrode surrounded by the climbing part.

16. The display panel according to claim 14, wherein in the cut groove and the first electrode surrounded by the cut groove, at least a partial area of an outer peripheral surface of the first electrode is exposed by the cut groove.

17. The display panel according to claim 8, wherein a material of at least one of the cutoff layer and the etching barrier layer is a transparent conductive material.

18. The display panel according to claim 1, wherein the light-emitting layer further comprises a plurality of light-emitting sub-layers connected in series, and at least one of the light-emitting sub-layers is connected in series to an adjacent light-emitting sub-layer through a charge generation layer.

19. The display panel according to claim 1, wherein the second electrode is recessed at the cut groove to form a recessed area.

20. A method of manufacturing a display panel, comprising:
forming a driving backplane;
forming a first electrode layer and a separation layer on one side of the driving backplane, wherein the first electrode layer comprises a plurality of first electrodes distributed at intervals; the separation layer comprises a support layer and a cutoff layer stacked in a direction away from the driving backplane; a material of the support layer is an insulating material and each of the first electrodes is exposed; an orthographic projection of the cutoff layer on the driving backplane and an orthographic projection of the first electrode on the driving backplane are spaced apart; the separation layer is configured with a cut groove located elsewhere of the first electrode, the cut groove comprises a first groove located on the support layer and a second groove located on the cutoff layer, an orthographic projection of at least one side wall of the second groove on the driving backplane is located between orthographic projections of boundaries of two side walls of the first groove away from a surface of the driving backplane on the driving backplane;
forming light-emitting layer covering the separation layer and the first electrode; and
forming a second electrode covering the light-emitting layer.

21. A display device, comprising the display panel according to claim 1.
